(19) United States
(12) Patent Application Publication
(10) Pub. No.: US 2003/0132818 A1
(43) Pub. Date: Jul. 17, 2003

(54) Manufacturing method of semiconductor device

(75) Inventors: Ryouhei Takai, Hyogo (JP); Shu Shimizu, Hyogo (JP)

Correspondence Address: McDERMOTT, WILL & EMERY, 600 13th Street, N.W., Washington, DC, 20005-3096, US

(73) Assignee: MITSUBISHI DENKI KABUSHIKI KAISHA

(21) Appl. No.: 10/338,638

(22) Filed: Jan. 9, 2003

(30) Foreign Application Priority Data
Jan. 17, 2002 (JP) 2002-008712

(51) Int. Cl. H01L 21/00; H03H 9/00; H01L 41/00

(52) U.S. Cl. 333/133

(57) ABSTRACT

Thermal oxide film and silicon nitride film are successively formed on a surface of silicon substrate. An opening is formed by conventional photolithography and etching. Field oxide film is formed by selective oxidation in the surface of the silicon substrate exposed at the bottom of the opening. When the measurement of the film thickness T of the silicon nitride film differs from its initially set value, the exposure dose in the photolithography for formation of the opening is changed from its initially set amount in accordance with a difference between the measurement and the initially set value of the film thickness, to change the resulting width of the opening from its initially set value. The length of the bird's beak is thus controlled, and the field oxide film is formed with a dimension as initially designed.

### BACKGROUND OF THE INVENTION

1. Field of the Invention

The present invention relates to a manufacturing method of a semiconductor device.

2. Description of the Background Art

Field oxide films manufactured by local oxidation of silicon (LOCOS) suffer irregular dimensional changes, making it difficult to form uniform birds' beaks. With advancement of element downsizing, effects of such variation in birds' beaks have become more serious, so that there is a need to form uniform birds' beaks more than ever before. Hereinafter, a conventional manufacturing method of a semiconductor device having a field oxide film will be described.

FIGS. 15 and 16A-16C are a flow chart and schematic cross sectional views, respectively, illustrating successive steps of a conventional method of manufacturing a semiconductor device having a field oxide film.

Referring to FIGS. 15 and 16A, a thermal oxide film 103 of about 10 nm thick is formed on a surface of a semiconductor substrate 104 made of silicon (Si). A silicon nitride film 102 of about 75 nm thick is then formed on thermal oxide film 103 (step S101). Here, a bird's beak of a field oxide film is less likely to extend as silicon nitride film 102 has a thicker film thickness T0. The bird's beak is more likely to extend with thinner film thickness T0.

Referring to FIGS. 15 and 16B, a photoresist 101 is applied on silicon nitride film 102. Photoresist 101 is subjected to exposure and development by conventional photolithography, to form a resist pattern 101 (step S102). Silicon nitride film 102 and thermal oxide film 103 are successively dry etched using this resist pattern 101 as a mask. An opening 106 is thus formed to expose a portion of the surface of semiconductor substrate 104. Resist pattern 101 is then removed by, e.g., ashing.

Here, the bird's beak of the field oxide film is more likely to extend at the time of selective oxidation as opening 106 has a wider width L0. With opening 106 of narrower width L0, the bird's beak is less likely to extend.

Referring to FIGS. 15 and 16C, the surface of semiconductor substrate 104 is subjected to selective oxidation using patterned thermal oxide film 103 and silicon nitride film 102 as masks. Thus, a field oxide film 105 having a thickness of about 500 nm is formed at the surface of semiconductor substrate 104 exposed at the bottom of opening 106 (step S103). Here, the bird's beak of field oxide film 105 is more likely to extend as the amount of oxidation at the selective oxidation is greater. The bird's beak is less likely to extend with a smaller amount of oxidation.

The conventional field oxide film 105 was formed in this manner.

As explained above, a length of the bird's beak would be regulated by controlling the film thickness TO of silicon nitride film 102, the width L0 of opening 106, and the amount of oxidation at the selective oxidation. These three steps, however, were controlled independently from each other, and it was difficult to form uniform birds' beaks with such separate controls.

### SUMMARY OF THE INVENTION

An object of the present invention is to provide a manufacturing method of a semiconductor device having a field oxide film permitting formation of uniform birds' beaks.

The manufacturing method of a semiconductor device according to an aspect of the present invention is a manufacturing method of a semiconductor device having a field oxide film which includes the steps of: forming a silicon nitride film on a main surface of a semiconductor substrate; forming an opening in the silicon nitride film to expose a portion of the main surface of the semiconductor substrate; and forming by oxidation the field oxide film in the main surface of the semiconductor substrate exposed at the bottom of the opening. In this method, a film thickness of the silicon nitride film is measured after the formation of the silicon nitride film and, when the measurement of the film thickness is different from an initially set value, an exposure dose at the time of forming the opening by photolithography is changed from its initially set value to change the resulting width of the opening from its initially set value.

If the film thickness of the silicon nitride film is greater than the initially set value, the bird's beak will become short, and thus, the dimension of the field oxide film will become smaller than its designed value. With the manufacturing method of a semiconductor device according to the aspect, however, the exposure dose is increased from the initially set value in accordance with the greater film thickness, to make the resulting width of the opening greater than the initially set value. Thus, the bird's beak extends, and accordingly, the dimension of the field oxide film can be adjusted to the designed value.

On the contrary, if the film thickness of the silicon nitride film is smaller than the initially set value, the bird's beak will become long, and the dimension of the field oxide film will become greater than its designed value. With the inventive method, however, the exposure dose is decreased from its initially set value in accordance with the smaller film thickness, to suppress extension of the bird's beak. Accordingly, the dimension of the field oxide film can be adjusted to the designed value.

The manufacturing method of a semiconductor device according to another aspect of the present invention is a manufacturing method of a semiconductor device having a field oxide film which includes the steps of: forming a silicon nitride film on a main surface of a semiconductor substrate; forming an opening in the silicon nitride film to expose a portion of the main surface of the semiconductor substrate; and forming by oxidation the field oxide film in the main surface of the semiconductor substrate exposed at the bottom of the opening. In this method, a film thickness of the silicon nitride film is measured after the formation of the silicon nitride film and, when the measurement of the film thickness is different from its initially set value, an oxidation amount at the time of the oxidation is changed from its initially set amount in accordance with a difference between the measurement and the initially set value of the film thickness.

If the film thickness of the silicon nitride film is greater than the initially set value, the bird's beak will become short, and thus, the dimension of the field oxide film will become smaller than its designed value. With the manufacturing method of a semiconductor device according to the present aspect, however, the oxidation amount is increased from its initially set amount in accordance with the greater film thickness, to make the bird's beak extend. Accordingly, the dimension of the field oxide film can be adjusted to the designed value.

Conversely, if the film thickness of the silicon nitride film is smaller than the initially set value, the bird's beak will become long, and the dimension of the field oxide film will become greater than the designed value. With the inventive method, however, the oxidation amount is decreased from its initially set amount in accordance with the smaller film thickness, to limit extension of the bird's beak. Accordingly, the dimension of the field oxide film can be adjusted to the designed value.

The manufacturing method of a semiconductor device according to yet another aspect of the present invention is a manufacturing method of a semiconductor device having a field oxide film which includes the steps of: forming a silicon nitride film on a main surface of a semiconductor substrate; forming an opening in the silicon nitride film to expose a portion of the main surface of the semiconductor substrate; and forming by oxidation the field oxide film in the main surface of the semiconductor substrate exposed at the bottom of the opening. In this method, a resulting width of the opening is measured and, when the measurement is different from an initially set value of the width, an oxidation amount at the time of oxidation is changed from its initially set amount in accordance with a difference between the measurement and the initially set value of the width of the opening.

If the width of the opening is greater than the initially set value, the bird's beak will become long, and thus, the dimension of the field oxide film will become greater than its designed value. With the manufacturing method of a semiconductor device according to the present aspect, however, the oxidation amount is decreased from the initially set amount in accordance with the wider width of the opening, to make the bird's beak short, and accordingly, the dimension of the field oxide film can be adjusted to the designed value.

On the contrary, if the width of the opening is smaller than the initially set value, the bird's beak will become short, and the dimension of the field oxide film will become smaller than its designed value. With the inventive method, however, the oxidation amount is increased from its initially set amount in accordance with the narrower width of the opening, to elongate the bird's beak. Accordingly, the dimension of the field oxide film can be adjusted to the designed value.

The control apparatus of the present invention is a control apparatus controlling a manufacturing method of a semiconductor device having a field oxide film which includes at least one of a first control unit and a second control unit. The first control unit compares a measurement of a film thickness of a silicon nitride film formed on a main surface of a semiconductor substrate with an initially set value of the film thickness of the silicon nitride film, and, when the measurement of the film thickness is different from the initially set value of the film thickness, controls such that either one of an exposure dose at the time of formation of an opening in the silicon nitride film and an oxidation amount at the time of oxidation for formation of the field oxide film is changed from its initially set amount. The second control unit compares a measurement of a width of the opening with an initially set value of the width of the opening, and, when the measurement of the width of the opening is different from the initially set value of the width of the opening, controls such that the oxidation amount at the time of oxidation for formation of the field oxide film is changed from its initially set amount.

According to the control device of the present invention, at least one of the first and second control units is provided. Therefore, in the manufacturing process of the field oxide film, if a preceding step has a condition that makes a bird's beak long (or short), a succeeding step is made to have a condition that makes the bird's beak short (or long). Accordingly, the dimension of the field oxide film can be adjusted to its designed value.

The control method according to an aspect of the present invention is a control method of controlling a manufacturing method of a semiconductor device having a field oxide film. The control method includes the steps of: comparing a measurement of a film thickness of a silicon nitride film formed on a main surface of a semiconductor substrate with an initially set value of the film thickness of the silicon nitride film; and, when the measurement of the film thickness is different from the initially set value of the film thickness, changing either one of an exposure dose at the time of forming an opening in the silicon nitride film and an oxidation amount at the time of oxidation for formation of the field oxide film.

With the control method according to the aspect of the present invention, the exposure dose for the formation of the opening or the oxidation amount at the time of oxidation is controlled in accordance with the change in film thickness of the silicon nitride film, to adjust the length of the bird's beak. Thus, the dimension of the field oxide film can be adjusted to its designed dimension.

The control method according to another aspect of the present invention is a control method controlling a manufacturing method of a semiconductor device having a field oxide film. The control method includes the steps of: comparing a measurement of a width of an opening of a silicon nitride film formed on a main surface of a semiconductor substrate with an initially set value of the width of the opening; and, when the measurement of the width is different from the initially set value of the width, changing an oxidation amount at the time of oxidation for formation of the field oxide film from its initially set amount.

With the control method according to the present aspect of the present invention, the oxidation amount at the time of oxidation is controlled in accordance with the actual width of the opening, to adjust the length of the bird's beak. Accordingly, the dimension of the field oxide film can be adjusted to its designed dimension.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a flow chart illustrating a manufacturing method of a semiconductor device having a filed oxide film according to a first embodiment of the present invention.

FIGS. 2A-2F are schematic cross sectional views illustrating the manufacturing method of a semiconductor device having a field oxide film of the first embodiment.

FIG. 3 is a flow chart illustrating a manufacturing method of a semiconductor device having a field oxide film according to a second embodiment of the present invention.

FIG. 4 is a top plan view of a wafer.

FIGS. 5A-5C are schematic cross sectional views illustrating the manufacturing method of a semiconductor device having a field oxide film of the second embodiment.

FIG. 6 is a flow chart illustrating a manufacturing method of a semiconductor device having a field oxide film according to a third embodiment of the present invention.

FIGS. 7A-7F are schematic cross sectional views illustrating the manufacturing method of a semiconductor device having a field oxide film of the third embodiment.

FIG. 8 is a flow chart illustrating a manufacturing method of a semiconductor device having a field oxide film according to a fourth embodiment of the present invention.

FIGS. 9A-9G are schematic cross sectional views illustrating the manufacturing method of a semiconductor device having a field oxide film of the fourth embodiment.

FIG. 10 is a flow chart illustrating a manufacturing method of a semiconductor device having a field oxide film according to a fifth embodiment of the present invention.

FIG. 11 is a top plan view of a wafer.

FIGS. 12A-12E are schematic cross sectional views illustrating the manufacturing method of a semiconductor device having a field oxide film of the fifth embodiment.

FIG. 13 is a block diagram illustrating a concept of an apparatus for controlling the manufacturing method of a semiconductor device having a file oxide film according to a sixth embodiment of the present invention.

FIG. 14 is a flow chart illustrating a method for controlling the manufacturing method of a semiconductor device having a field oxide film of the sixth embodiment.

FIG. 15 is a flow chart illustrating a conventional manufacturing method of a semiconductor device having a field oxide film.

FIGS. 16A-16C are schematic cross sectional views illustrating the conventional manufacturing method of a semiconductor device having a field oxide film.

### DESCRIPTION OF THE PREFERRED EMBODIMENTS

Hereinafter, embodiments of the present invention will be described with reference to the drawings.

First Embodiment

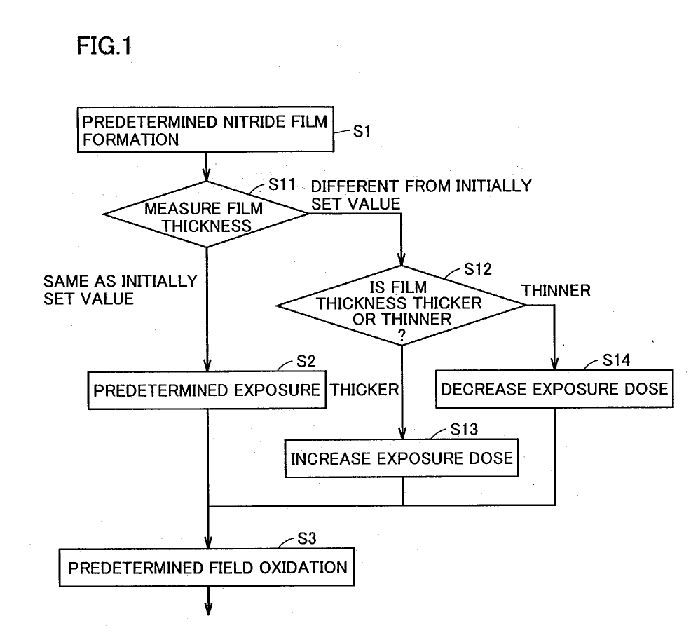

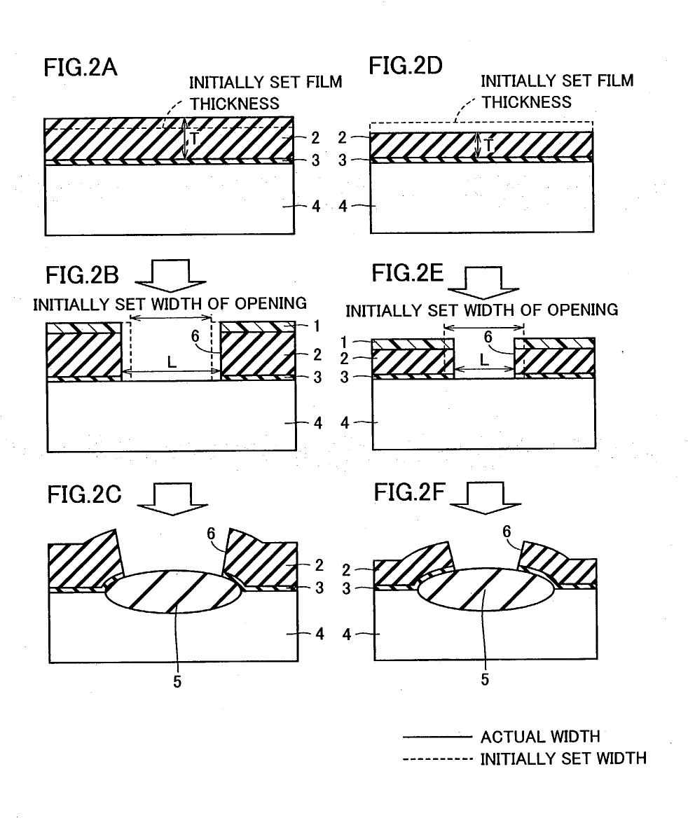

Referring to FIGS. 1, 2A and 2D, a thermal oxide film 3 of about 10 nm thick is formed on a surface of a semiconductor substrate 4 made of, e.g., silicon, and a silicon nitride film 2 of about 75 nm thick is formed thereon (step S1). The film thickness T of silicon nitride film 2 is then measured (step S11).

Referring to FIGS. 1, 2B and 2E, a photoresist 1 is applied on silicon nitride film 2, and is subjected to exposure and development by conventional photolithography. The exposure of photoresist 1 is carried out with a predetermined exposure dose (initial exposure dose) if the film thickness T of silicon nitride film 2 is as initially set (step S2). If thickness T of silicon nitride film 2 is different from the initially set value, it is determined whether film thickness T of silicon nitride film 2 is greater or smaller than the initially set value (step S 12). If it is thicker, the exposure is conducted with an exposure dose greater than the initially set amount (step S13). If thinner, the exposure is carried out with an exposure dose smaller than the initially set amount (step S14).

Photoresist 1 is patterned by the exposure and development. Silicon nitride film 2 and thermal oxide film 3 are dry etched using the patterned photoresist 1 as a mask, so that an opening 6 is formed in silicon nitride film 2 and thermal oxide film 3 to expose a portion of the surface of silicon substrate 4. Here, when the exposure is carried out with an exposure dose greater than the initially set amount, the resulting width L of opening 6 becomes wider than its initially set value. With the exposure using an exposure dose smaller than the initially set amount, resulting width L of opening 6 becomes narrower than the initially set value. Thereafter, photoresist 1 is removed by ashing, for example.

Referring to FIGS. 1, 2C and 2F, silicon substrate 4 is subjected to selective oxidation using patterned silicon nitride film 2 and thermal oxide film 3 for masking. A field oxide film 5 of, e.g., 500 nm thick is thus formed at the surface of silicon substrate 4 exposed at the bottom of opening 6 (step S3).

A semiconductor device having field oxide film 5 is thus formed.

As described above, in the case where the measurement of film thickness T of silicon nitride film 2 is greater than an initially set value, the bird's beak tends to become short. This would make the dimension of field oxide film 5 smaller than its designed value. In the present embodiment, however, the exposure dose of photoresist 1 can be increased from its initially set amount in accordance with the greater film thickness T. The width L of opening 6 then becomes wider than its initially set value, allowing the bird's beak to extend. Accordingly, it is possible to adjust the dimension of field oxide film 5 to the initially set value.

If the measurement of film thickness T of silicon nitride film 2 is smaller than the initially set value, the bird's beak tends to extend, resulting in field oxide film 5 having a dimension greater than the designed value. In such a case, according to the present embodiment, the exposure dose of photoresist 1 is lessened from the initially set amount in accordance with the smaller film thickness T. Thus, the resulting width L of opening 6 becomes smaller than the initially set value, and elongation of the bird's beak is limited. Accordingly, the dimension of field oxide film 5 can be adjusted to the initially set value.

As such, the length of the bird's beak of field oxide film 5 can be regulated by controlling the exposure dose of photoresist 1 in accordance with film thickness T of silicon nitride film 2. Accordingly, adjustment to make the dimensions of field oxide films 5 uniform in the corresponding pattern portions at respective shots, respective wafers or respective lots becomes possible.

It is noted that the initially set values of film thickness T of silicon nitride film 2 and width L of opening 6 as well as the initially set amount of the exposure dose for formation of opening 6 are derived from pattern designing. More specifically, once a circuit pattern is designed, dimensions (initially set values) of respective portions of the field oxide film are decided. The initially set values of film thickness T of silicon nitride film 2 and width L of opening 6 as well as the initially set amount of the exposure dose for formation of opening 6 are then decided such that the field oxide film is formed in the dimensions thus decided.

Second Embodiment

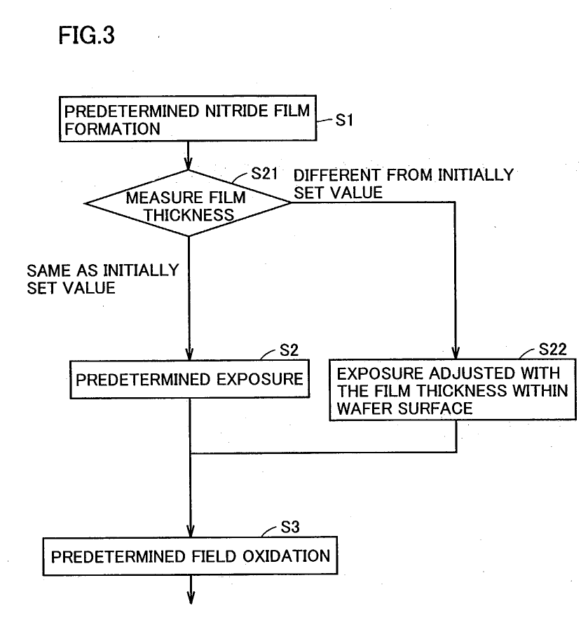

Referring to FIGS. 3 and 5A, a thermal oxide film 3 of about 10 nm thick is formed on a surface of a semiconductor substrate 4 made of, e.g., silicon, and a silicon nitride film 2 of about 75 nm thick is formed thereon (step S1). The film thickness T of silicon nitride film 2 is then measured at various portions over a wafer surface (step S21).

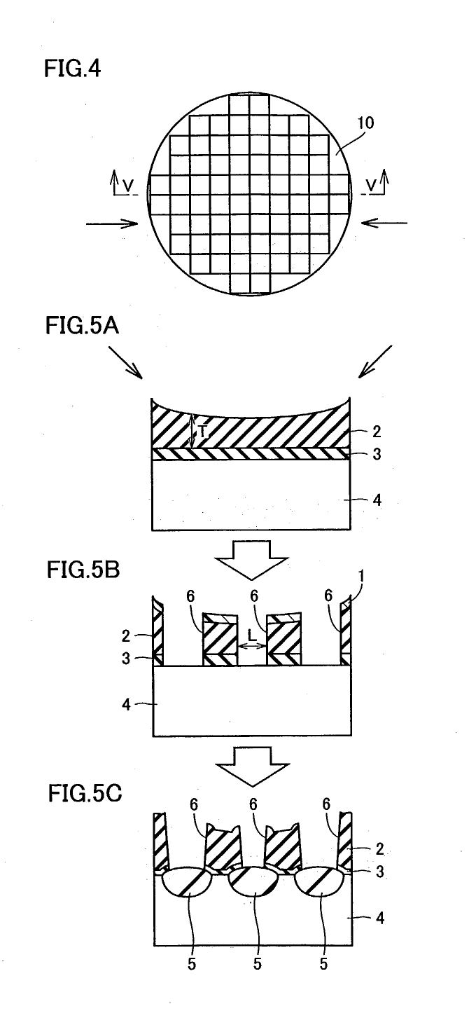

Silicon nitride film 2 is formed by, e.g., low pressure chemical vapor deposition (LPCVD). With this method, gas is sprayed onto a wafer 10 placed in a chamber from its periphery, as shown in FIG. 4. Film thickness T of silicon nitride film 2 thus formed tends to be thinner at the inner portion of the wafer surface and thicker at the peripheral portion thereof.

Referring to FIGS. 3 and 5B, a photoresist 1 is applied on silicon nitride film 2, and is subjected to exposure and development by conventional photolithography. Here, the photolithography for the exposure of photoresist 1 is carried out in the manner of step and repeat. More specifically, photoresist 1 on a single wafer is exposed with a plurality of shots, with a reticle pattern (mask pattern) being displaced for each shot from one another.

This allows the exposure dose to be changed for each shot over the wafer surface in accordance with the variation in film thickness T of silicon nitride film 2 throughout the wafer surface. For example, the exposure of one shot is carried out with a predetermined exposure dose (initially set amount) if the film thickness T of silicon nitride film 2 is as initially set in a region to be subjected to the relevant shot (step S2). If the film thickness T of silicon nitride film 2 is different from the initially set value in the region to be subjected to the shot, however, the exposure dose is changed from the initially set amount according to the difference (step S22).

More specifically, the exposure dose of a certain shot is increased from the initially set amount if film thickness T of silicon nitride film 2 in the region to be exposed by the relevant shot is thicker than the initially set value. The exposure is carried out with an exposure dose smaller than the initially set amount when film thickness T of silicon nitride film 2 in the relevant region is thinner than the initially set value.

Photoresist 1 thus patterned by the exposure and development is used as a mask to dry-etch silicon nitride film 2 and thermal oxide film 3. Thus, an opening 6 is formed exposing a portion of the surface of silicon substrate 4. Here, the actual width L of opening 6 becomes greater than initially set when the exposure dose of photoresist 1 is greater than initially set. The width L of opening 6 becomes smaller than the initially set value when the exposure dose is smaller than the initially set amount. Thereafter, photoresist 1 is removed by, e.g., ashing.

Referring to FIGS. 3 and 5C, silicon substrate 4 is subjected to selective oxidation using patterned silicon nitride film 2 and thermal oxide film 3 for masking. A field oxide film 5 of about 500 nm thick, for example, is thus formed at the surface of silicon substrate 4 exposed at the bottom of opening 6 (step S3).

The cross sections shown in FIGS. 5A-5C each correspond to a portion of the cross section taken along the line V-V in FIG. 4.

A semiconductor device having field oxide film 5 is thus formed.

According to the present embodiment, even if silicon nitride film 2 has film thicknesses T varying throughout the wafer surface, the exposure dose can be changed for each shot in accordance with the variation in film thicknesses T of silicon nitride film 2. Therefore, adjustment to uniform the dimensions of the field oxide films located in the corresponding pattern portions at respective shots becomes possible.

Third Embodiment

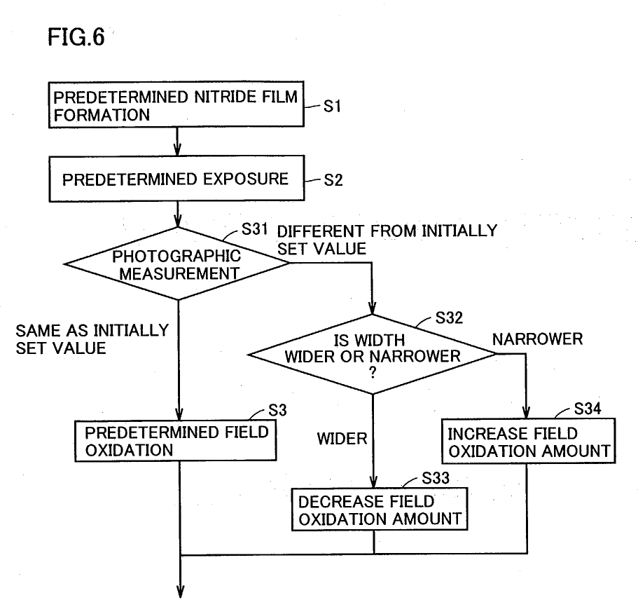

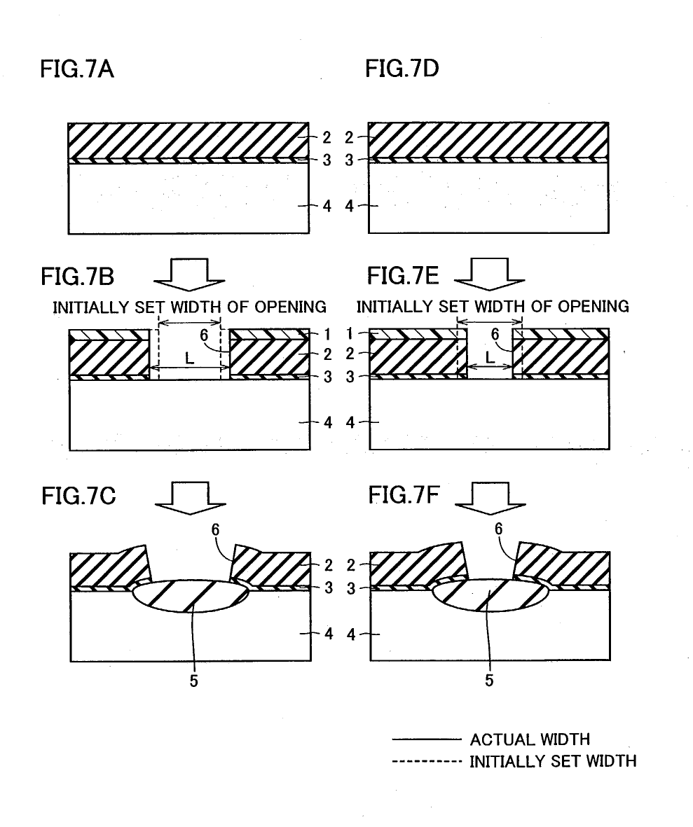

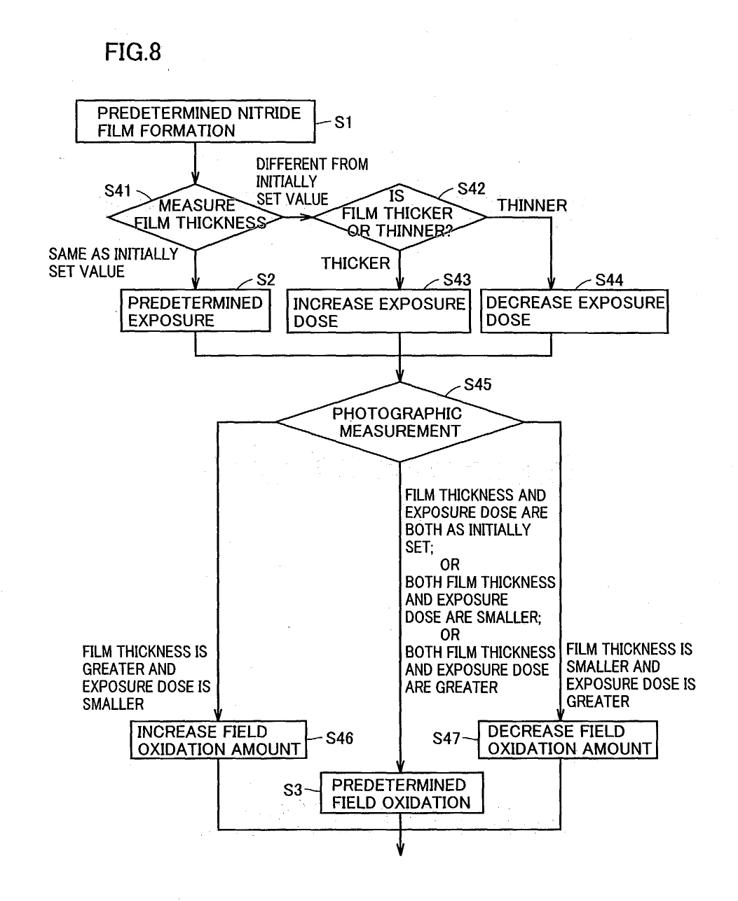

Referring to FIGS. 6, 7A and 7D, a thermal oxide film 3 of about 10 nm thick is formed on a surface of a semiconductor substrate 4 made of, e.g., silicon, and a silicon nitride film 2 of about 75 nm thick is formed thereon (step S1).

Referring to FIGS. 6, 7B and 7E, a photoresist 1 is applied on silicon nitride film 2. Photoresist 1 is patterned through exposure and development by conventional photolithography. The exposure is carried out with a predetermined exposure dose (initially set amount) (step S2). Using the patterned photoresist 1 as a mask, silicon nitride film 2 and thermal oxide film 3 are dry etched successively. An opening 6 is thus formed exposing a portion of the surface of silicon substrate 4, and the resulting width L of the opening 6 is measured by photography (step S31). Thereafter, photoresist 1 is removed by ashing, for example.

Referring to FIGS. 6, 7C and 7F, silicon substrate 4 is subjected to selective oxidation using patterned silicon nitride film 2 and thermal oxide film 3 for masking, to form a field oxide film 5 at the surface of silicon substrate 4 exposed at the bottom of opening 6. When the resulting width L of opening 6 is as initially set, the selective oxidation is carried out with a predetermined oxidation amount (initially set amount) (step S3). If the width L of opening 6 created is different from the initially set value, it is determined whether the actual width L of opening 6 is wider or narrower than the initially set value (step S32). If it is wider, the selective oxidation is carried out with an oxidation amount smaller than the initially set amount (step S33), whereas it is carried out with an oxidation amount greater than the initially set amount if the width L is narrower than the initially set value (step S34).

A semiconductor device having field oxide film 5 is thus manufactured.

As described above, if the width L of opening 6 created is wider than its initially set value, the bird's beak tends to extend, resulting in field oxide film 5 with its dimension exceeding the initially set value. According to the present embodiment, however, the oxidation amount at the time of selective oxidation is reduced from the initially set amount in accordance with the wider width L of opening 6, to limit the extension of the bird's beak. Thus, the dimension of field oxide film 5 is adjusted to the initially set value.

If the actual width L of opening 6 is narrower than the initially set value, the bird's beak tends to become shorter, in which case, the dimension of field oxide film 5 would become smaller than the initially set value. In this embodiment, however, the oxidation amount at the selective oxidation is increased in accordance with the narrower width L of opening 6, to make the bird's beak elongate. The dimension of field oxide film 5 is thus made equal to the initially set value.

As explained above, the length of the bird's beak of field oxide film 5 can be adjusted by controlling the oxidation amount in accordance with the width L of opening 6 created. Accordingly, adjustment to make the dimensions of field oxide films 5 uniform in the corresponding pattern portions at respective shots, respective wafers or respective lots becomes possible.

Fourth Embodiment

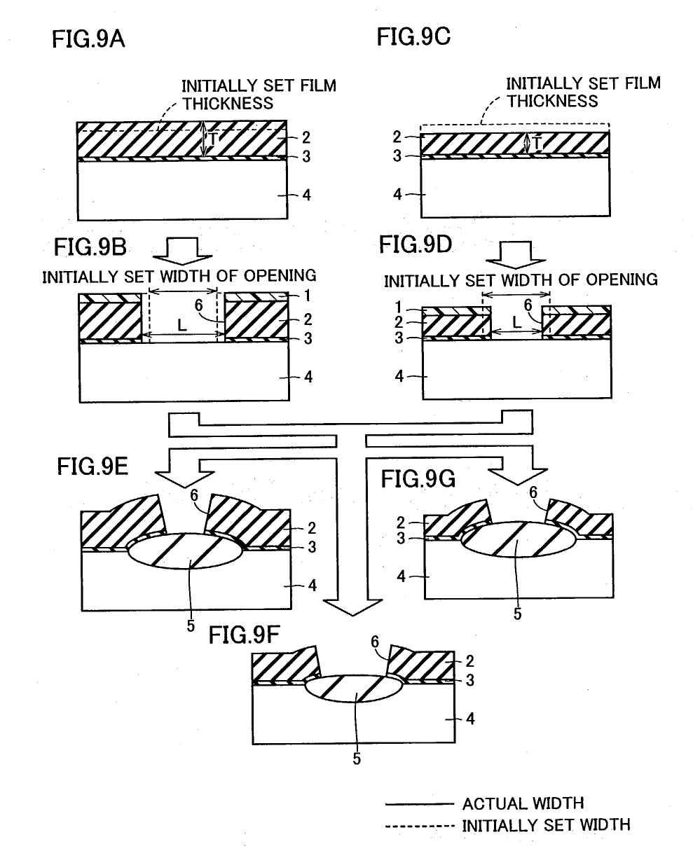

Referring to FIGS. 8, 9A and 9C, a thermal oxide film 3 of about 10 nm thick is formed on a surface of a semiconductor substrate 4 made of, e.g., silicon, and a silicon nitride film 2 of about 75 nm thick is formed thereon (step S 1). The film thickness T of silicon nitride film 2 is then measured (step S41).

Referring to FIGS. 8, 9B and 9D, a photoresist 1 is applied on silicon nitride film 2, and is patterned through exposure and development by conventional photolithography.

The exposure of photoresist 1 is carried out with a predetermined exposure dose (initially set amount) if film thickness T of silicon nitride film 2 is as initially set (step S2). If it is different from the initially set value, it is determined whether the film thickness T of silicon nitride film 2 is thicker or thinner than the initially set value (step S42). If thicker, the exposure dose is increased from the initially set amount (step S43). If thinner, the exposure dose is decreased from the initially set amount (step S44).

Using patterned photoresist 1 as a mask, silicon nitride film 2 and thermal oxide film 3 are dry etched successively, to form an opening 6 exposing a portion of the surface of silicon substrate 4. The resulting width L of opening 6 is then measured by photography (step S45). Thereafter, photoresist 1 is removed by, e.g., ashing.

Referring to FIGS. 8, 9E-9G, using patterned silicon nitride film 2 and thermal oxide film 3 for masking, the surface of silicon substrate 4 exposed at the bottom of opening 6 is subjected to selective oxidation to form a field oxide film 5 therein.

Here, the oxidation amount at the time of selective oxidation is adjusted as follows. If film thickness T of silicon nitride film 2 and width L of opening 6 are both as initially set, if both film thickness T of silicon nitride film 2 and width L of opening 6 are greater than their initially set values, or if both film thickness T of silicon nitride film 2 and width L of opening 6 are smaller than their initially set values, then the selective oxidation is carried out with the oxidation amount as initially set (step S3). If film thickness T of silicon nitride film 2 is greater than the initially set value and width L of opening 6 is smaller than the initially set value, the selective oxidation is carried out with the oxidation amount greater than the initially set amount (step S46). If film thickness T of silicon nitride film 2 is smaller than the initially set value and width L of opening 6 is greater than the initially set value, then the oxidation amount at the selective oxidation is reduced from the initially set amount (step S47).

A semiconductor device having field oxide film 5 is thus manufactured.

According to the present embodiment, three factors of film thickness T of silicon nitride film 2, width L of opening 6 and the oxidation amount at the time of selective oxidation are related to each other. This further facilitates adjustment of the dimension of field oxide film 5 to its initially set value. Accordingly, it becomes possible to make the field oxide films in the same pattern portions uniform in dimension for each shot, wafer or lot.

Fifth Embodiment

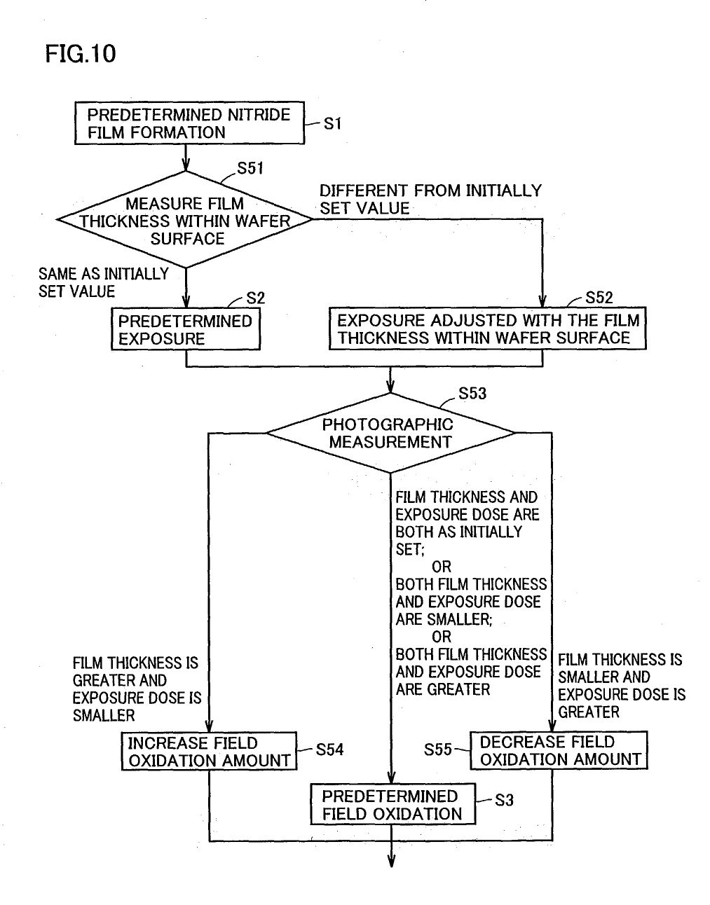

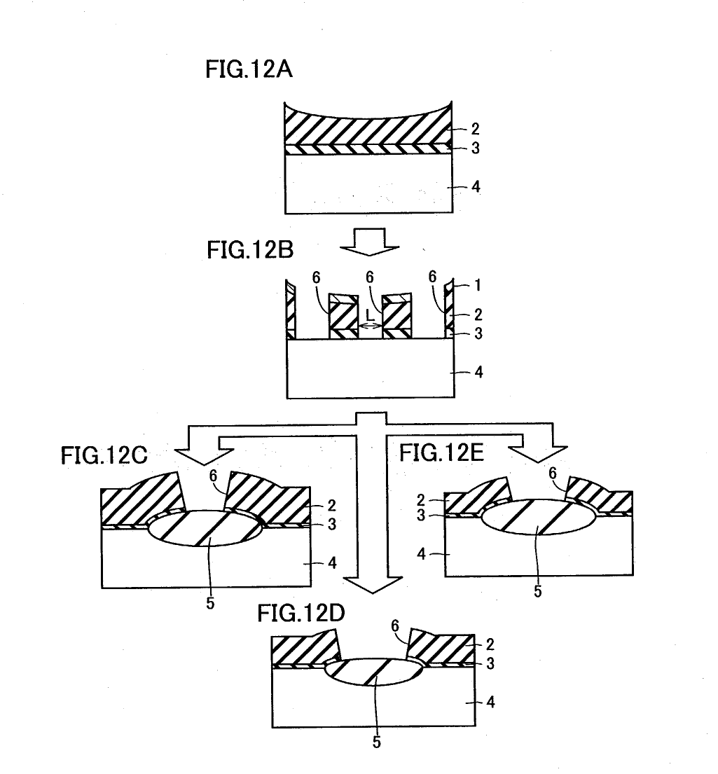

Referring to FIGS. 10 and 12A, a thermal oxide film 3 of about 10 nm thick is formed on a surface of a semiconductor substrate 4 made of, e.g., silicon, and a silicon nitride film 2 of about 75 nm thick is formed thereon (step S1). The film thickness T of silicon nitride film 2 is then measured at various portions over a wafer surface (step S51).

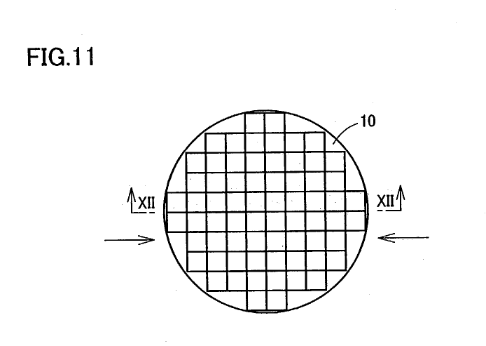

Silicon nitride film 2 is formed by, e.g., LPCVD, in which case, gas is sprayed onto a wafer 10 placed in a chamber from its periphery, as shown in FIG. 11. Film thickness T of silicon nitride film 2 thus formed tends to be thinner at the inner portion of the wafer surface and thicker at the peripheral portion thereof.

Referring to FIGS. 10 and 12B, a photoresist 1 is applied on silicon nitride film 2, and is subjected to exposure and development by conventional photolithography. The photolithography for the exposure of photoresist 1 is carried out in the manner of step and repeat. More specifically, photoresist on a single wafer is exposed with a plurality of shots, with a reticle pattern (mask pattern) being displaced for each shot from one another.

This allows the exposure dose to be changed for each shot over the wafer surface in accordance with the variation in film thickness T of silicon nitride film 2. For example, the exposure of one shot is carried out with a predetermined exposure dose (initially set amount) if the film thickness T of silicon nitride film 2 in a region to be subjected to the relevant shot is as initially set (step S2). If the film thickness T of silicon nitride film 2 in the relevant region is different from the initially set value, the exposure dose is changed from the initially set amount accordingly (step S52).

More specifically, the exposure dose is increased from the initially set amount if film thickness T of silicon nitride film 2 is greater than the initially set value in the region to be exposed by the shot. The exposure is carried out with a smaller exposure dose when film thickness T of silicon nitride film 2 in the relevant region is smaller than the initially set value.

Photoresist 1 thus patterned by the exposure and development is used as a mask to dry-etch silicon nitride film 2 and thermal oxide film 3, so that an opening 6 exposing a portion of the surface of silicon substrate 4 is formed. The resulting width L of opening 6 is then measured by photography (step S53). Here, the actual width L of opening 6 becomes greater than initially set when the exposure dose of photoresist 1 is greater than initially set. The width L of opening 6 becomes smaller than the initially set value when the exposure dose is smaller than the initially set amount. Thereafter, photoresist 1 is removed by, e.g., ashing.

Referring to FIGS. 10 and 12C-12E, silicon substrate 4 is subjected to selective oxidation using patterned silicon nitride film 2 and thermal oxide film 3 for masking. A field oxide film 5 with a thickness of, e.g., about 500 nm is thus formed at the surface of silicon substrate 4 exposed at the bottom of opening 6.

Here, the oxidation amount at the time of selective oxidation is adjusted as follows. If film thickness T of silicon nitride film 2 and width L of opening 6 are both as initially set, if both film thickness T of silicon nitride film 2 and width L of opening 6 are greater than their initially set values, or if both film thickness T of silicon nitride film 2 and width L of opening 6 are smaller than their initially set values, then the selective oxidation is carried out with the oxidation amount as initially set (step S3). If film thickness T of silicon nitride film 2 is greater than the initially set value and width L of opening 6 is smaller than the initially set value, then the selective oxidation is carried out with the oxidation amount greater than the initially set amount (step S54). If film thickness T of silicon nitride film 2 is smaller than the initially set value and width L of opening 6 is greater than the initially set value, then the oxidation amount at the time of selective oxidation is reduced from the initially set amount (step S55).

The cross sections shown in FIGS. 12A-12E each correspond to a portion of the cross section taken along the line XII-XII in FIG. 11.

A semiconductor device having field oxide film 5 is thus manufactured.

According to the present embodiment, even if film thickness T of silicon nitride film 2 varies over the wafer surface, three factors of film thickness T of silicon nitride film 2, width L of opening 6 and the oxidation amount at the selective oxidation are related to each other, and further, the exposure dose is adjusted for each shot in accordance with the variation in film thickness T of silicon nitride film 2. Accordingly, it is possible to further uniform the dimensions of the field oxide films in the same pattern portions for each shot.

Sixth Embodiment

In this embodiment, method and apparatus for controlling the manufacturing method of a semiconductor device having a field oxide film described in the first through fifth embodiments above will be described.

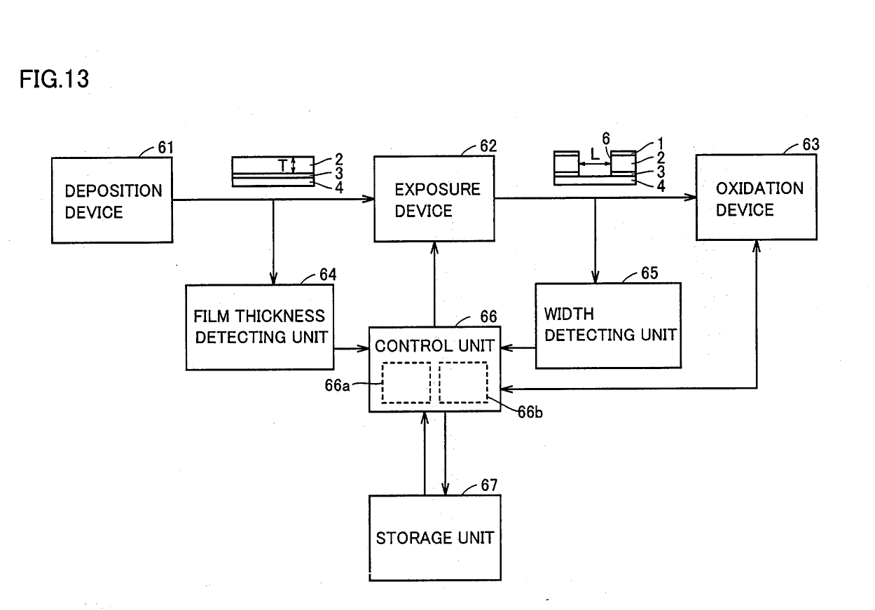

Referring to FIG. 13, a control apparatus includes, among others, a film thickness detecting unit 64 detecting, e.g., film thickness T of silicon nitride film 2, a width detecting unit 65 for measurement of actual width L of opening 6, a control unit 66 and a storage unit 67.

Control unit 66 includes first and second control units 66a and 66b. First control unit 66a compares film thickness T (actual measurement) of silicon nitride film 2 detected by film thickness detecting unit 64 with an initially set value of the film thickness stored in storage unit 67. Based on the comparison data, it applies a signal for control of the exposure dose to an exposure device 62, or applies a signal for control of the oxidation amount at the time of selective oxidation to an oxidation device 63. Second control unit 66b compares width L (actual measurement) of opening 6 detected by width detecting unit 65 with an initially set value of the width stored in storage unit 67 and, based on the comparison data, applies a signal for control of the oxidation amount at the selective oxidation to oxidation device 63.

A control method employing this control apparatus will now be described.

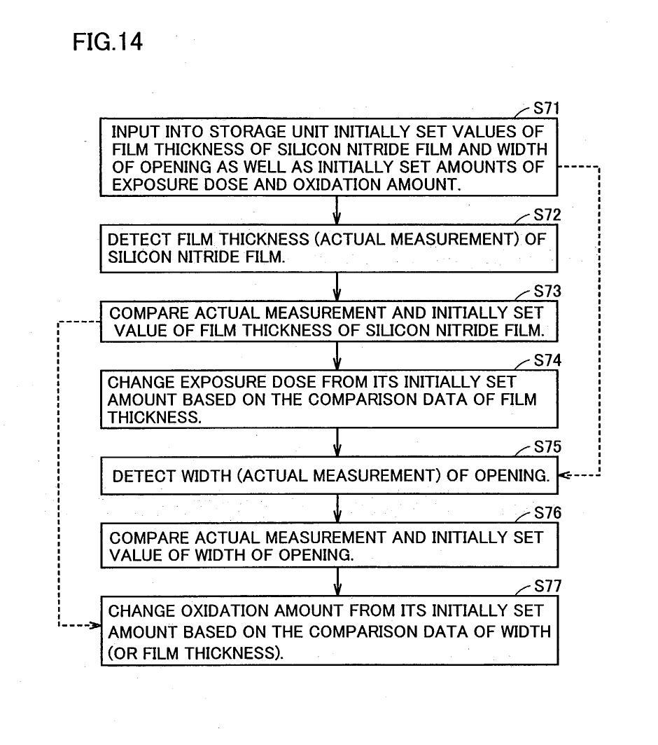

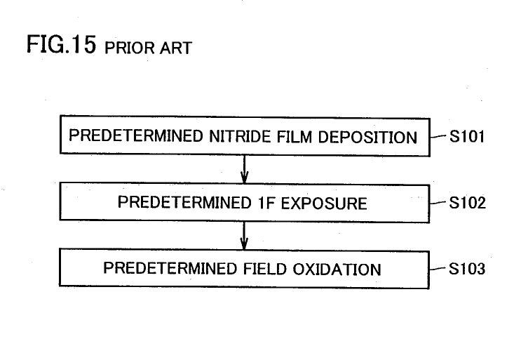

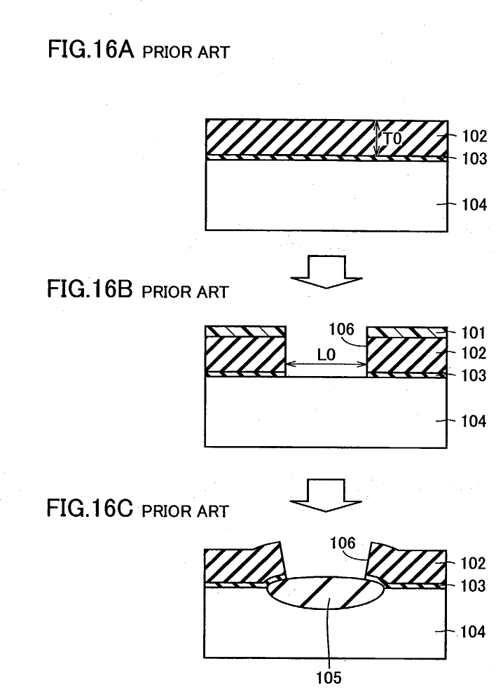

Referring to FIGS. 13 and 14, a circuit pattern is designed, and accordingly, dimensions of portions of the field oxide film are decided. For formation of the field oxide film with the intended dimensions, initially set values for film thickness T of silicon nitride film 2 and width L of opening 6 as well as initially set amounts for the exposure dose at the exposure for formation of opening 6 and the oxidation amount at the selective oxidation are decided and input to storage unit 67 (step S71).

Next, film thickness T (actual measurement) of silicon nitride film 2 deposited by a deposition device 61 is detected by film thickness detecting unit 64 (step S72), and is input into first control unit 66a of control unit 66. In first control unit 66a, the film thickness T (actual measurement) of silicon nitride film 2 input therein is compared with the initially set value of the film thickness stored in storage unit 67 (step S73). Based on the comparison data of the film thickness, a control signal of the exposure dose for exposure of the photoresist is applied to exposure device 62 (step S74), or a control signal of the oxidation amount for selective oxidation is applied to oxidation device 63 (step S77).

The control signal of the exposure dose is applied such that the exposure dose is increased from the initially set amount when film thickness T (actual measurement) of silicon nitride film 2 is greater than initially set, and such that the exposure dose is decreased from the initially set amount when film thickness T (actual measurement) of silicon nitride film 2 is smaller than the initially set value. The control signal of the oxidation amount is applied such that the oxidation amount is increased from the initially set amount when film thickness T (actual measurement) of silicon nitride film 2 is greater than initially set, and such that the oxidation amount is decreased from the initially set amount when film thickness T (actual measurement) of silicon nitride film 2 is smaller than the initially set value.

Next, using the photoresist exposed by exposure device 62 and developed thereafter as a mask, silicon nitride film 2 and thermal oxide film 3 are successively dry etched to form an opening 6. The resulting width L of opening 6 is detected by width detecting unit 65 (step S75), and input to second control unit 66b of control unit 66. In this second control unit 66b, width L input (actual measurement) is compared with an initially set value of the width of opening 6 stored in storage unit 67 (step S76). Based on the comparison data of the width, a control signal of the oxidation amount for selective oxidation is applied to oxidation device 63 (step S77).

The control signal of the oxidation amount is applied such that the oxidation amount is decreased from the initially set amount when width L (actual measurement) of opening 6 is greater than initially set, and such that the oxidation amount is increased from the initially set amount when width L (actual measurement) of opening 6 is smaller than the initially set value.

The selective oxidation is carried out at oxidation device 63 based on the control signal of the oxidation amount applied from first or second control unit 66a, 66b, to form a field oxide film at the surface of the semiconductor substrate.

In the control described above, the exposure dose and/or the oxidation amount at the selective oxidation may be controlled based on the film thickness of silicon nitride film 2. The oxidation amount at the selective oxidation may be controlled based on the actual width of opening 6 accompanied by, or not accompanied by, the control of the exposure dose based on the film thickness of silicon nitride film 2.

As explained above, preferably in the manufacturing method of a semiconductor device according to an aspect of the present invention, if the silicon nitride film has its film thickness varying over the wafer surface, exposure is carried out a plurality of times in the wafer surface, with the exposure dose at each exposure changed from one another. This makes it possible to change the widths of the openings to be formed in the corresponding pattern portions at the respective times of exposure. As such, despite the variation in film thickness of the silicon nitride film over the wafer surface, the dimensions of the field oxide films located in the corresponding pattern portions at the respective times of exposure can be made uniform throughout the wafer surface.

In the manufacturing method of a semiconductor device according to the aspect of the present invention, preferably, the width of the opening is measured and, if the actual measurement of the width is different from the initially set value, the oxidation amount in the oxidation process is changed from the initially set amount in accordance with the difference between the actual measurement and the initially set value of the width of the opening. For example, if the actual width of the opening is greater than the initially set value, the bird's beak would extend and the dimension of the field oxide film would become greater than initially set. In such a case, the oxidation amount is reduced from the initially set amount in accordance with the wider opening, to suppress the undesired extension of the bird's beak. Accordingly, the dimension of the field oxide film can be adjusted to the designed value. Conversely, if the actual width of the opening is smaller than the initially set value, the bird's beak would become short and the dimension of the field oxide film would become smaller than initially set. In this case, the oxidation amount is increased from the initially set amount in accordance with the narrowed opening, to let the bird's beak extend as desired. Therefore, the dimension of the field oxide film can be adjusted to the designed value.

Preferably in the manufacturing method of a semiconductor device according to another aspect of the present invention, if the silicon nitride film has its film thickness varying in the wafer surface, exposure is carried out a plurality of times over the wafer surface, with the exposure doses differentiated from each other. The widths of the openings to be opened in the corresponding pattern portions at the respective times of exposure can be changed. Therefore, even if the film thickness of the silicon nitride film varies over the wafer surface, the field oxide films uniform in dimension can be formed in the corresponding pattern portions at the respective times of exposure throughout the wafer surface.

Preferably, the control method of the present invention further includes the step of comparing an actual measurement of the width of the opening with the initially set value thereof when the exposure dose for formation of the opening is changed from the initially set value, and the step of changing the oxidation amount at the time of selective oxidation for formation of the field oxide film from the initially set amount when the actual measurement of the width of the opening differs from the initially set value. By controlling the oxidation amount at the time of oxidation in accordance with the change of the width of the opening, the length of the bird's beak can be regulated, and accordingly, the dimension of the field oxide film can be adjusted to the designed value.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A manufacturing method of a semiconductor device having a field oxide film, comprising the steps of:
forming a silicon nitride film in a main surface of a semiconductor substrate;
forming an opening in said silicon nitride film to expose a portion of the main surface of said semiconductor substrate; and
forming by oxidation a field oxide film in the main surface of said semiconductor substrate exposed at a bottom of said opening;
wherein when a film thickness of said silicon nitride film measured after the formation of said silicon nitride film is different from an initially set value of said film thickness, an exposure dose in photolithography for formation of said opening is changed from its initially set amount in accordance with a difference between the measurement and the initially set value of said film thickness to change a resulting width of said opening from its initially set value.

2. The manufacturing method of a semiconductor device according to claim 1, wherein when the film thickness of said silicon nitride film varies over a wafer surface, exposure is conducted a plurality of times with different exposure doses over said wafer surface, such that the widths of said openings to be formed in corresponding pattern portions at the respective times of said exposure are changed.

3. The manufacturing method of a semiconductor device according to claim 1, wherein a width of said opening is measured and, when the measurement of said width differs from an initially set value of said width, an oxidation amount in said oxidation is changed from its initially set amount in accordance with a difference between the measurement and the initially set value of said width of said opening.

4. A manufacturing method of a semiconductor device having a field oxide film, comprising the steps of:
forming a silicon nitride film in a main surface of a semiconductor substrate;
forming an opening in said silicon nitride film to expose a portion of the main surface of said semiconductor substrate; and
forming by oxidation said field oxide film in the main surface of said semiconductor substrate exposed at a bottom of said opening;
wherein when a film thickness of said silicon nitride film measured after the formation of said silicon nitride film is different from an initially set value of said film thickness, an oxidation amount in said oxidation is changed from its initially set amount in accordance with a difference between the measurement and the initially set value of said film thickness.

5. The manufacturing method of a semiconductor device according to claim 4, wherein when the film thickness of said silicon nitride film varies over a wafer surface, exposure is carried out a plurality of times with different exposure doses over said wafer surface such that widths of said openings to be formed in corresponding pattern portions at the respective times of said exposure are changed.

6. A manufacturing method of a semiconductor device having a field oxide film, comprising the steps of:
forming a silicon nitride film in a main surface of a semiconductor substrate;
forming an opening in said silicon nitride film to expose a portion of the main surface of said semiconductor substrate; and
forming by oxidation said field oxide film in the main surface of said semiconductor substrate exposed at a bottom of said opening;
wherein when a resulting width of said opening measured is different from an initially set value of said width, an oxidation amount in said oxidation is changed from its initially set amount in accordance with a difference between the measurement and the initially set value of said width of said opening.
